(19) United States
(12) Patent Application Publication
(10) Pub. No.: US 2003/0177636 A1
(43) Pub. Date: Sep. 25, 2003

(54) Method of manufacturing power light emitting diodes

(75) Inventors: Ming-Te Lin, (US); Ming-Yao Lin, (US)

Correspondence Address: TROXELL LAW OFFICE PLLC, Suite 1404, 5205 Leesburg Pike, Falls Church, VA, 22041, US

(73) Assignee: Para Light Electronic, Ltd.

(21) Appl. No.: 10/102,972

(22) Filed: Mar. 22, 2002

(51) Int. Cl. H05K 3/20; B23P 17/00

(52) U.S. Cl. 29/832; 29/831; 29/412

(57) ABSTRACT

A method of manufacturing power light emitting diodes mainly includes the steps of cutting a rolled dual-thickness sheet material into a plurality of continuous conductive frames in a roll form; cutting the rolled continuous conductive frames into segments, the number of conductive frames included in each segment depending on the molds designed for each packaging of the conductive frames with epoxy resin or silicon material; positioning chips, marking lines, and applying bonding agent on the conductive frames; packaging the conductive frames to obtain continuous half-finished products; and cutting apart the continuous half-finished products and cutting off legs to obtain finished products. The above-described method is developed based on conventional power transistor manufacturing process and enables automated mass-production of power light emitting diodes. The obtained finished products have enlarged radiating elements for radiating heat produced by the chips and can therefore use high current to produce high-intensity lights.

### FIELD OF THE INVENTION

The present invention relates to a method of manufacturing power light emitting diodes, and more particularly to a method of manufacturing power light emitting diodes by cutting a dual-thickness sheet material into continuous conductive frames, positioning chips, marking lines, and applying bonding agents on the conductive frames, and packaging the conductive frames. The obtained products have enhanced heat-radiating power and produce high-intensity lights, and are therefore suitable for producing illuminating devices.

### BACKGROUND OF THE INVENTION

Light emitting diodes developed in early stages are generally for use as indicators or displays, such as brake lights. Due to limitations in forming a chip layer thereof, the early-stage light emitting diodes do not emit lights having a density sufficient for illuminating purpose. For example, general light emitting diodes, being limited by their radiating structure, can use only a low current about 20 mA to 50 mA. Such low current is not suitable for light emitting diodes for illuminating purpose that requires high power and high current.

FIGS. 1 and 2 shows a power light emitting diode, model No. 00-0001, produced by LumiLeds Lighting, U.S. This type of power light emitting diode includes a structure that is currently adopted for most commercially available power light emitting diodes and it requires a current about 350 mA to produce high brightness. While the power light emitting diode shown in FIGS. 1 and 2 produces high brightness, it also produces large amount of heat. Therefore, it is necessary for the power light emitting diode to possess good radiating power.

The power light emitting diode shown in FIGS. 1 and 2 includes a chip 91 that is directly connected to a circuit board 92, and a sleeve 93 that is mounted around the chip 91 to fixedly hold a case 94 housing the chip 91 therein.

To manufacture the above-described power light emitting diode, first fix the chip 91 on the circuit board 92, and then fix the sleeve 93 around the chip 91 with a bonding agent. Thereafter, the case 94 is compressed onto a top of the sleeve 93 to complete the power light emitting diode shown in FIG. 1. Wherein, the chip 91 is directly connected to the circuit board 92 to obtain good radiating effect. However, the above-described power light emitting diode involves in very complicate manufacturing procedures in which a plurality of parts and components must be assembled manually that increases the manufacturing cost and, accordingly, the selling price of the product. If it were desired to produce an illuminating device with a plurality of the above-described conventional power light emitting diodes, the resultant illuminating device would inevitably require a manufacturing cost much higher than that for general bulbs or other types of illuminating devices.

### SUMMARY OF THE INVENTION

A primary object of the present invention is to provide a method of manufacturing power light emitting diodes that enables automated and mass production of differently configured power light emitting diodes to largely reduce the manufacturing cost thereof, so that it is possible to produce illuminating devices with multiple power light emitting diodes at market-acceptable cost.

To achieve the above and other objects, the method of manufacturing power light emitting diodes according to the present invention mainly includes the steps of preparing raw material for manufacturing the power light emitting diodes; processing the raw material to form a dual-thickness sheet material in the roll form; cutting the dual-thickness sheet material in predetermined manners so that a plurality of continuous conductive frames are formed; positioning chips, marking lines, and applying bonding agent on each of the plurality of continuous conductive frames; cutting the continuous conductive frames into segments, each of which including a fixed number of conductive frames decided by molds designed for packaging the light emitting diodes, packaging the conductive frames on the segments to obtain half-finished products; and cutting the half-finished products into individual finished products of power light emitting diodes.

With the above method, the conductive frames for forming the power light emitting diodes can be more conveniently produced, machined, stored, and transported.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein

FIG. 1 is an assembled perspective view of a conventional power light emitting diode;

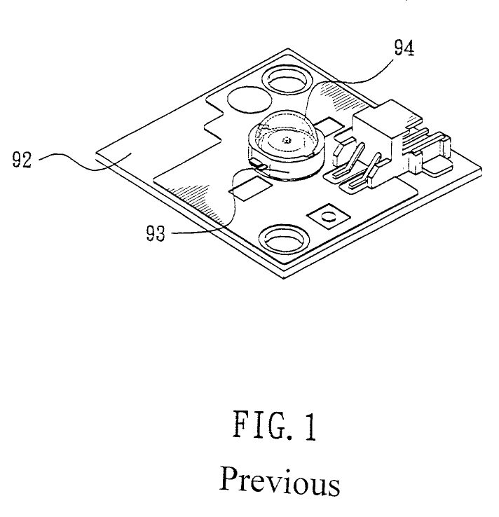

FIG. 2 is an exploded perspective view of the conventional power light emitting diode of FIG. 1;

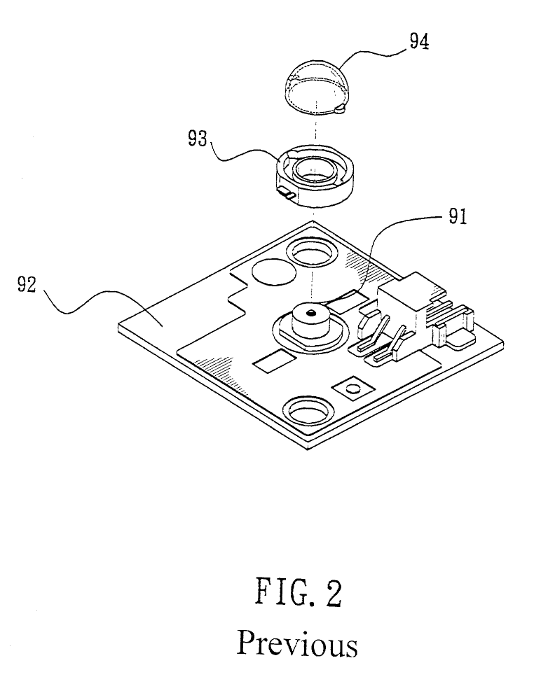

FIG. 3 is a flowchart of a method of manufacturing power light emitting diodes according to a first embodiment of the present invention, wherein a thick sheet of copper is processed to form a dual-thickness sheet material for manufacturing a plurality of continuous conductive frames;

FIG. 4 is a flowchart of a method of manufacturing power light emitting diodes according to a second embodiment of the present invention, wherein a thin sheet of copper is processed to form a dual-thickness sheet material for manufacturing a plurality of continuous conductive frames;

FIG. 5 schematically illustrates a first step of the method of the present invention for manufacturing power light emitting diodes;

FIG. 6 schematically illustrates a second step of the method of the present invention for manufacturing power light emitting diodes;

FIG. 7 schematically illustrates a third step of the method of the present invention for manufacturing power light emitting diodes;

FIG. 8 schematically illustrates a fourth step of the method of the present invention for manufacturing power light emitting diodes;

FIG. 9 schematically illustrates a fifth step of the method of the present invention for manufacturing power light emitting diodes;

FIG. 10 schematically illustrates a sixth step of the method of the present invention for manufacturing power light emitting diodes;

FIG. 11 schematically illustrates a seventh step of the method of the present invention for manufacturing power light emitting diodes;

FIG. 12 schematically illustrates an eighth step of the method of the present invention for manufacturing power light emitting diodes; and

FIG. 13 schematically illustrates a ninth step of the method of the present invention for manufacturing power light emitting diodes.

### DETAILED DESCRIPTION OF THE PREFERRED EMBODIMENTS

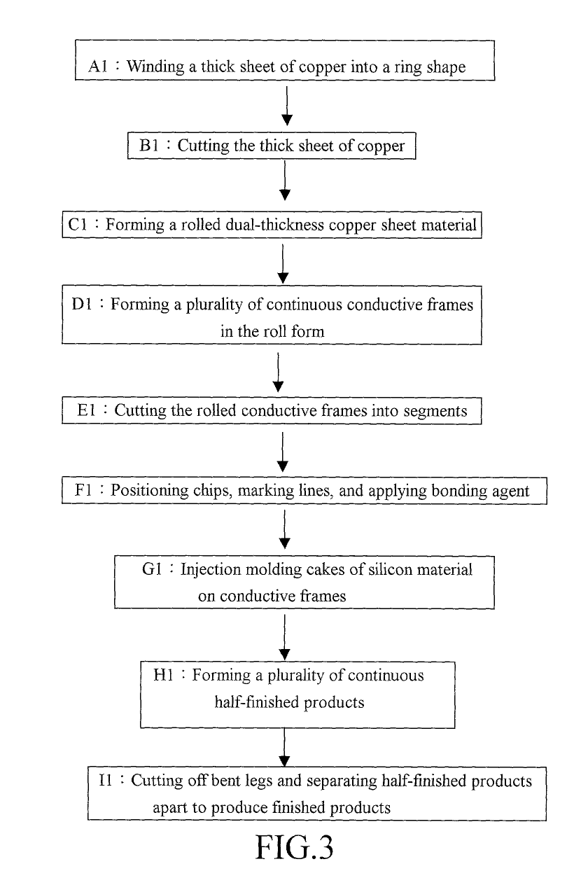

Please refer to FIG. 3 that is a flowchart showing steps A1 to I1 included in a method of manufacturing power light emitting diodes according to a first embodiment of the present invention.

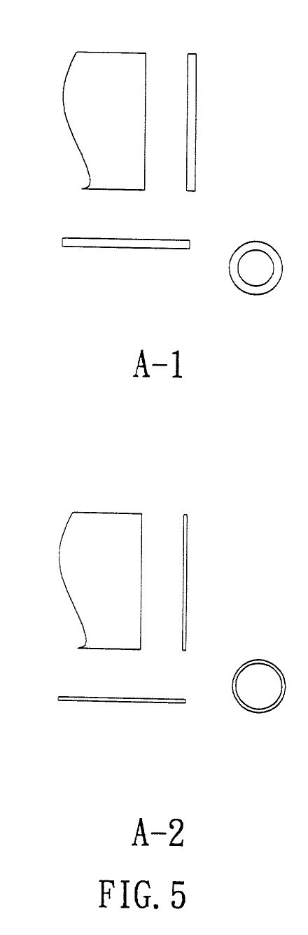

In the first step A1, a thick sheet of copper having a thickness within the range from 2 mm to 3 mm is prepared for manufacturing a plurality of continuous conductive frame. The prepared sheet copper is wound into an individual ring, as shown in part A-1 of FIG. 5.

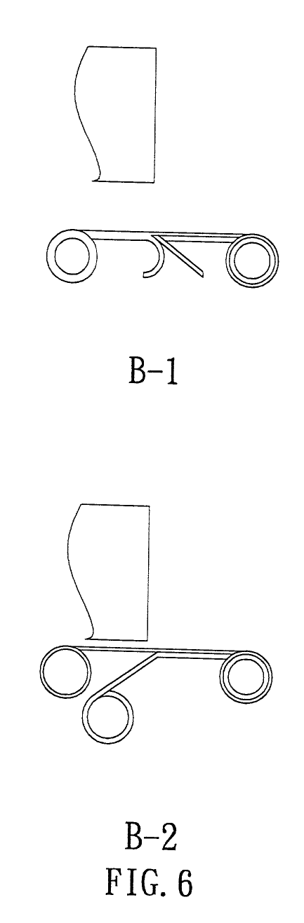

In the second step B1, the ring-shaped thick sheet of copper is subjected to cutting in a predetermined manner, as shown in part B-1 of FIG. 6.

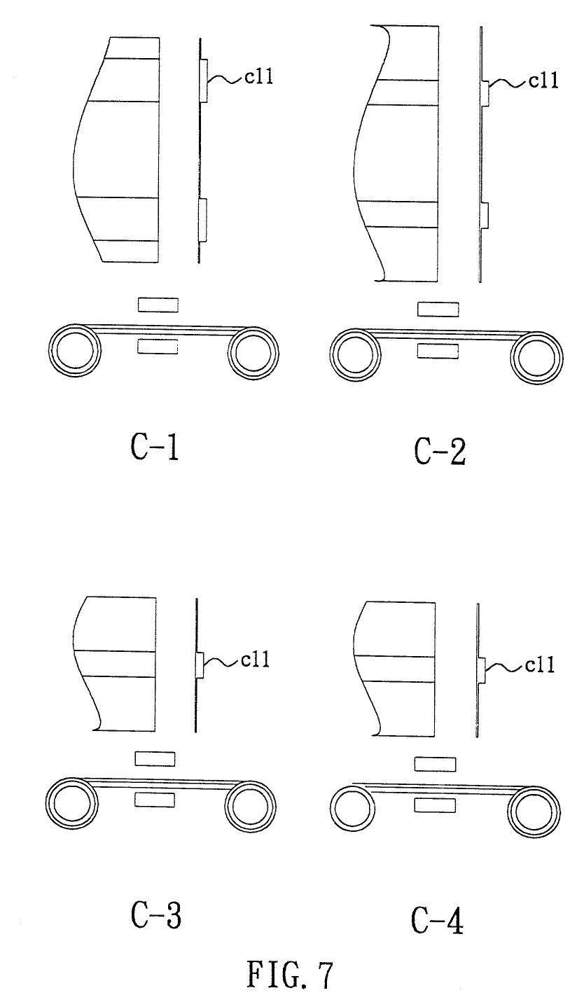

In the third step C1, the thick sheet of copper having been subjected to particular cutting is formed into a rolled dual-thickness copper sheet, as shown in parts C-1 and C-2 of FIG. 7. From side views included in parts C-1 and C-2 of FIG. 7, it can be seen that raised portions c11 are formed on the copper sheet for making the conductive frames for positioning chips thereon.

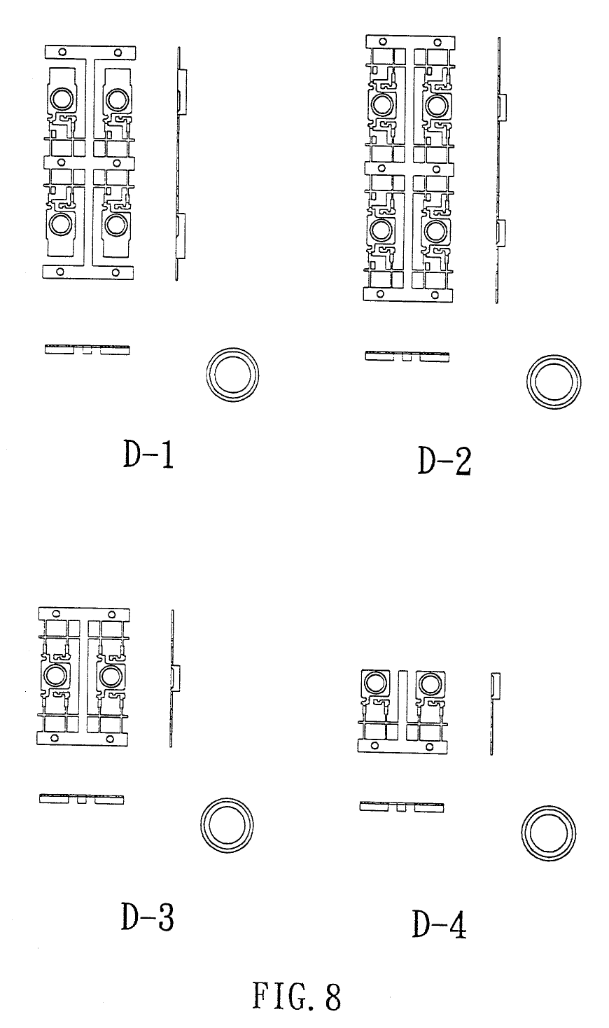

In the fourth step D1, the dual-thickness copper sheet is subjected to further cutting in predetermined manners to form a roll of continuous conductive frames, as shown in parts D-1 and D-2 of FIG. 8. Wherein, circles included in parts D-1 and D-2 indicate the resultant continuous conductive frames are wound into a roll.

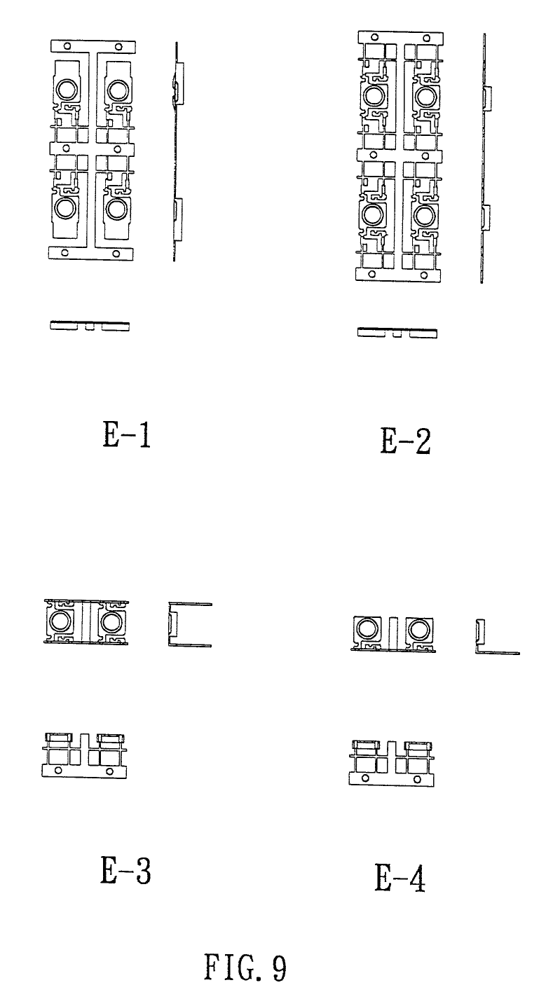

In the fifth step E1, the roll of continuous conductive frames is cut into individual segments, each of which including a fixed number of conductive frames corresponding to the amount of light emitting diodes to be produced in each injection molding, as shown in parts E-1 and E-2 of FIG. 9.

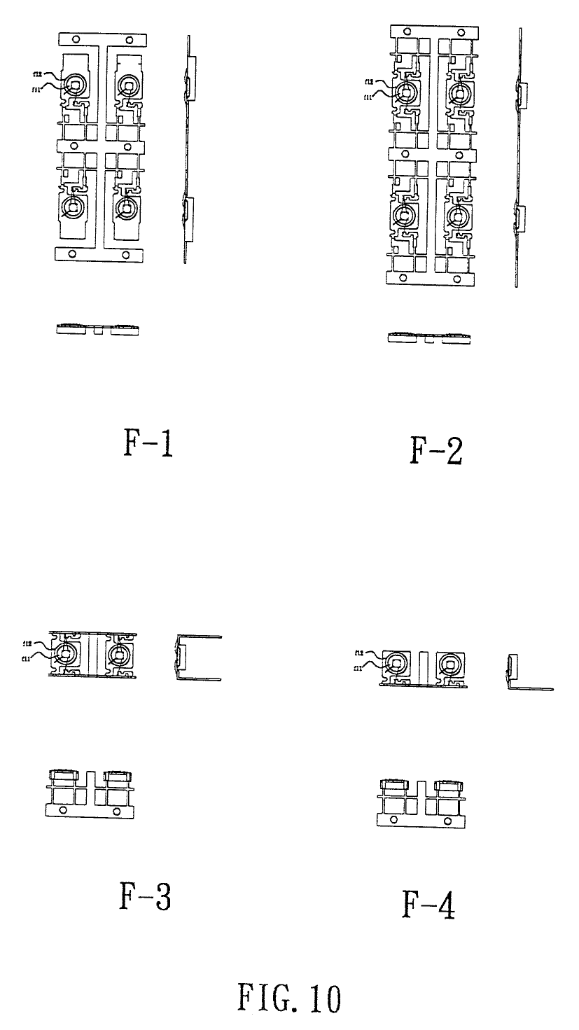

In the sixth step F1, further processes, such as positioning of chip f11, marking of lines f12, and applying of bonding agent, which may be silicon resin or epoxy resin, are performed on every conductive frame, as shown in parts F-1 and F-2 of FIG. 10.

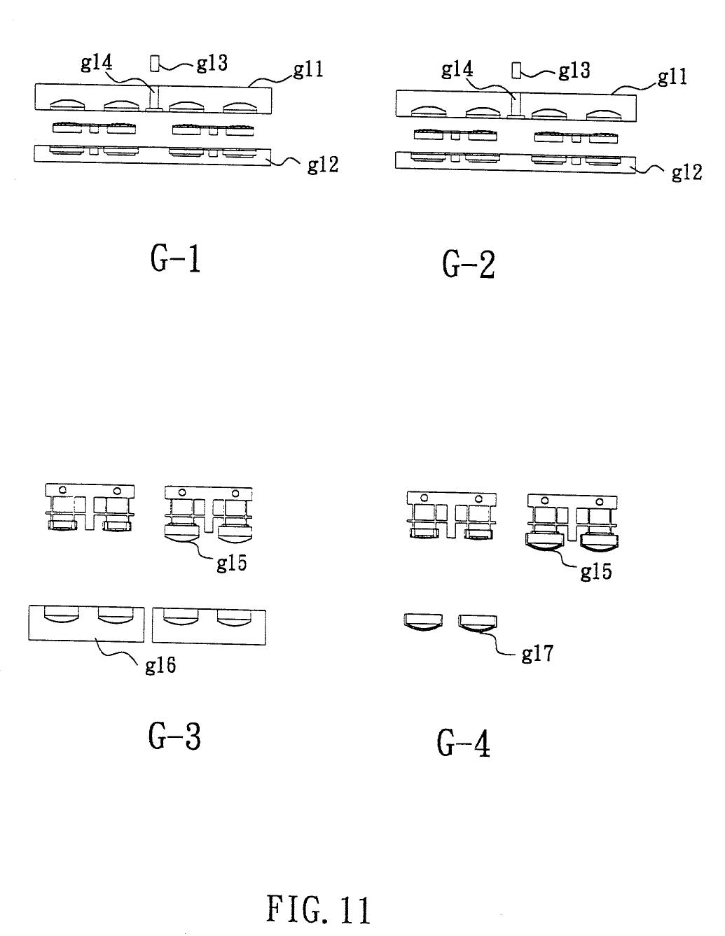

In the seventh step G1, injection molding a cake of silicon on each individual conductive frame via a mold is performed, as shown in parts G-1 and G-2 of FIG. 11. Wherein, the mold for performing the injection molding includes an upper mold g11 and a lower mold g12, and a silicon material g13 for forming the cake of silicon is injected into the mold via an injection port g14 on the upper mold g11.

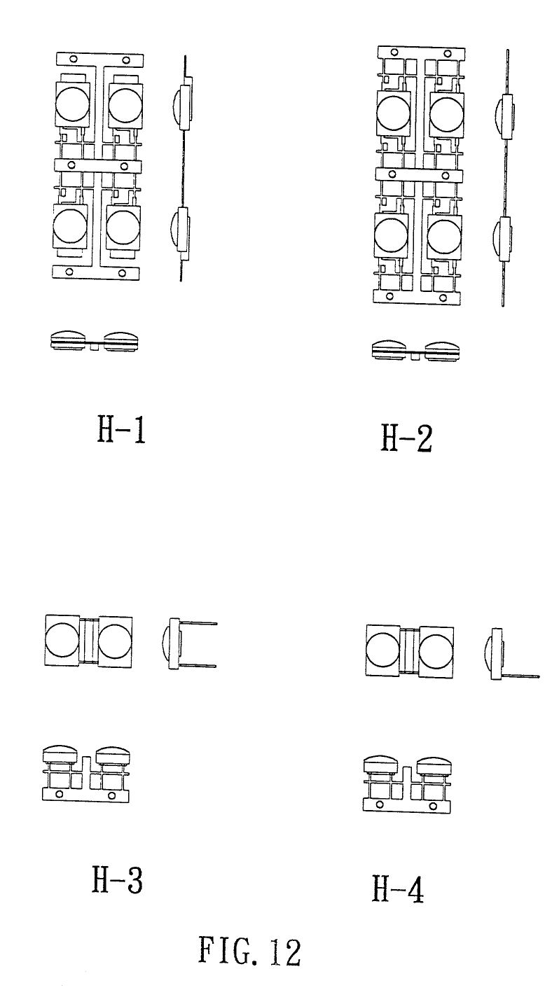

In the eighth step H1, stripping of mold is performed to obtain half-finished products in the form of a continuous roll, as shown in parts H-1 and H-2 of FIG. 12.

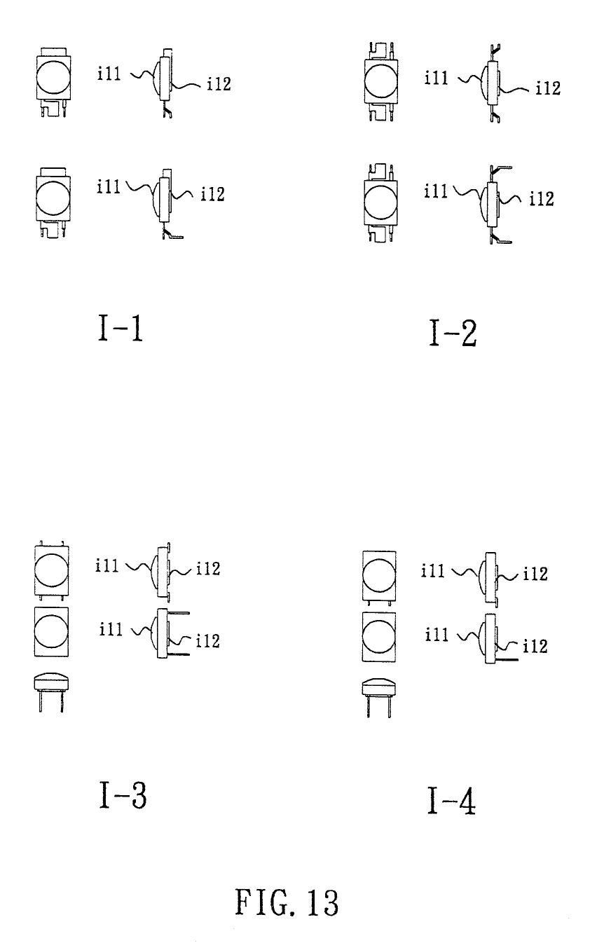

In the ninth step I1, bent legs on the continuous half-finished products are cut off to form individual finished products of power light emitting diodes, as shown in parts I-1 and I-2 of FIG. 13.

The finished power light emitting diodes obtained in the method according to the first embodiment of the present invention as shown in parts I-1 and I-2 of FIG. 13 all include a silicon portion ill that downward extends to a lower side of the conductive frame. A radiating element i12 is attached to a bottom of each silicon portion i11, allowing the power light emitting diode manufactured in the method of the present invention to function with a high current about 350 mA and therefore emit high-intensity lights. Wherein, the finished products shown in part I-1 of FIG. 13 are power light emitting diodes having plate-type contacts, while the finished products shown in part I-2 of FIG. 13 are power emitting diodes having pin-type contacts.

What is to be noted is the roll of continuous conductive frames is cut in the fifth step E1 into individual segments, each of which includes n×n conductive frames extended in a flat plane to match with the mold designed for the subsequent injection molding in the seventh step G1, so that mass-production of power light emitting diodes in the method of the present invention can be effectuated.

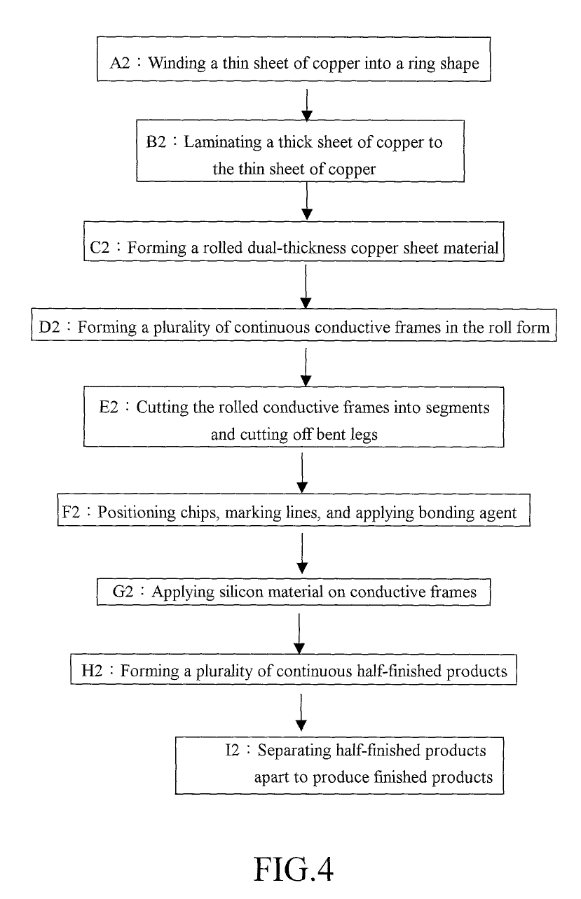

Please now refer to FIG. 4 that is a flowchart showing steps A2 to I2 included in a method of manufacturing power light emitting diode according to a second embodiment of the present invention.

In the first step A2, a thin sheet of copper having a thickness within the range from 0.4 mm to 0.8 mm is prepared for manufacturing a plurality of continuous conductive frames. The prepared thin copper sheet is wound into an individual ring, as shown in part A-2 of FIG. 5.

In the second step B2, the ring-shaped thin copper sheet is laminated to a thick sheet of copper, as shown in part B-2 of FIG. 6.

In the third step C2, the laminated copper sheet is formed into a rolled dual-thickness copper sheet material, as shown in parts C-3 and C-4 of FIG. 7. From side views included in parts C-3 and C-4 of FIG. 7, it can be seen that the copper sheet material for making the continuous conductive frames has raised portions c11 formed thereon for positioning of chips thereat.

In the fourth step D2, the dual-thickness copper sheet material is subjected to further cutting in predetermined manners to form a roll of continuous conductive frames, as shown in parts D-3 and D-4 of FIG. 8. Wherein, circles included in parts D-3 and D-4 indicate the resultant continuous conductive frames are wound into a roll.

In the fifth step E2, the roll of continuous conductive frames is cut into individual segments, each of which including a fixed number of conductive frames corresponding to the amount of cakes of silicon to be produced in each time of silicon application, as shown in parts E-3 and E-4 of FIG. 9.

In the sixth step F2, further processes, such as positioning of chip f11, marking of lines f12, and applying of bonding agent, which may be silicon resin or epoxy resin, are performed on every conductive frame, as shown in parts F-3 and F-4 of FIG. 10.

In the seventh step G2, applying of silicon to form a cake of silicon g15 on each individual conductive frame is performed. In part G-3 of FIG. 11, silicon material is directly filled into molds g16 and the conductive frames are pressed into the molds g16 to fix the cakes of silicon g15 to the conductive frames. In part G-4 of FIG. 11, individual cases g17 are first formed for applying silicon material thereinto, and then the conductive frames are assembled to the cases g16.

In the eighth step H2, half-finished products in a continuous form are obtained, as shown in parts H-3 and H-4 of FIG. 12.

In the ninth step I2, the continuous half-finished products are cut into individual finished products of power light emitting diodes, as shown in parts I-3 and I-4 of FIG. 13.

The finished power light emitting diodes obtained in the method according to the second embodiment of the present invention as shown in parts I-3 and I-4 of FIG. 13 all include a silicon portion ill that downward extends to a lower side of the conductive frame. A radiating element i12 is attached to a bottom of each silicon portion i11, allowing the power light emitting diode manufactured in the method of the present invention to function with a high current about 350 mA and therefore emit high-intensity lights. Wherein, the finished products shown in part I-3 of FIG. 13 are power light emitting diodes having four pin-type contacts, upper ones of which are horizontal and lower ones of which are vertical; and the finished products shown in part I-4 of FIG. 13 are power emitting diodes having two pin-type contacts, an upper one of which is horizontal and the lower one of which is vertical.

From the above descriptions, it is understood the method of the present invention uses either thick or thin copper sheet as raw material to produce a rolled dual-thickness copper sheet material, which is then subjected to cutting in predetermined manners to form a plurality of continuous conductive frames. On these continuous conductive frames, chips are positioned, lines are marked, bonding agent is applied, and then packaging is performed to obtain half-finished products. Thereafter, the half-finished products are cut apart to form individual finished products of power light emitting diodes. The method of manufacturing power light emitting diodes according to the present invention is developed based on the manufacturing process for conventional power transistors but has simplified structure to enable mass production of power light emitting diodes at reduced manufacturing cost, and accordingly, the forming of illuminating devices assembled from multiple light emitting diodes.

What is claimed is:

1. A method of manufacturing power light emitting diodes, comprising the steps of:
preparing raw material for manufacturing said power light emitting diodes;
processing said raw material to form a dual-thickness sheet material in the roll form;
cutting said dual-thickness sheet material in predetermined manners so that a plurality of continuous conductive frames are formed;
positioning chips, marking lines, and applying bonding agent on said plurality of continuous conductive frames;
packaging said continuous conductive frames to obtain a plurality of continuous half-finished products; and
cutting said continuous half-finished products into individual finished products of said power light emitting diodes.

2. The method of manufacturing power light emitting diodes as claimed in claim 1, wherein said raw material is a thick sheet of copper having a thickness within the range from 2 mm to 3 mm and being adapted to wind into a ring shape.

3. The method of manufacturing power light emitting diodes as claimed in claim 2, wherein said thick sheet of copper is formed into said dual-thickness sheet material by way of cutting in a predetermined manner, and said dual-thickness sheet material is then cut to form said plurality of continuous conductive frames.

4. The method of manufacturing power light emitting diodes as claimed in claim 3, wherein said plurality of continuous conductive frames are in the form of a roll before said packaging step.

5. The method of manufacturing power light emitting diodes as claimed in claim 4, wherein said plurality of continuous conductive frames in the form of a roll are cut into segments before being packaged, and each of said segments including a fixed number of said conductive frames corresponding to an amount of light emitting diodes to be produced in each injection molding with molds designed for said packaging step.

6. The method of manufacturing power light emitting diodes as claimed in claim 1, wherein said packaging step is performed by injection molding of silicon material with molds.

7. The method of manufacturing power light emitting diodes as claimed in claim 5, wherein said segments of said continuous conductive frames extend in a flat plane.

8. The method of manufacturing power light emitting diodes as claimed in claim 1, wherein said raw material is a thin sheet of copper having a thickness within the range from 0.4 mm to 0.8 mm and being adapted to wind into a ring shape.

9. The method of manufacturing power light emitting diodes as claimed in claim 8, wherein said thin sheet of copper is formed into said dual-thickness sheet material by laminating an additional thick sheet of copper thereto, and said dual-thickness sheet material is then cut to form said plurality of continuous conductive frames.

10. The method of manufacturing power light emitting diodes as claimed in claim 1, wherein said packaging step is performed by way of applying silicon material on said continuous conductive frames in a predetermined manner.

11. The method of manufacturing power light emitting diodes as claimed in claim 10, wherein said step of applying silicon material is performed by directly filling said silicon material into molds and pressing said conductive frames into said molds.

12. The method of manufacturing power light emitting diodes as claimed in claim 10, wherein said step of applying silicon material is performed by forming individual cases and then applying said silicon material into said cases, and then assembling said conductive frames to said cases.
